(19) United States
(12) Patent Application Publication
(10) Pub. No.: US 2005/0237788 A1
(43) Pub. Date: Oct. 27, 2005

(54) Magnetic memory and recording method thereof

(76) Inventors: Hiroshi Kano, Kanagawa (JP); Hiroyuki Ohmori, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 11/100,914

(22) Filed: Apr. 7, 2005

(30) Foreign Application Priority Data
Apr. 16, 2004 (JP) P2004-121915

(51) Int. Cl. G11C 19/08

(52) U.S. Cl. 365/158

(57) ABSTRACT

A magnetic memory includes magnetic memory elements 3 and 5 having memory layers capable of storing information by the magnetized state of a magnetic material, in which a plurality of magnetic memory elements 3 and 5 is electrically connected in series or in parallel to each other near an intersection point between two kinds of interconnections 1 and 6 which cross each other and between the two kinds of the interconnections 1 and 6, threshold values of recording electric currents by which information can be recorded on a plurality of magnetic memory elements 3 and 5 are made different from each other and the memory layers of the respective magnetic memory elements 3 and 5 comprise different information storage units. Thus, the magnetic memory becomes able to record much more information per unit area.

### CROSS REFERENCES TO RELATED APPLICATIONS

The present invention contains subject manner related to Japanese Patent Application JP 2004-121915 filed in the Japanese Patent Office on Apr. 16, 2004, the entire contents of which being incorporated herein by reference.

### BACKGROUND OF THE INVENTION

1. Field of the Invention

The present invention relates generally to a magnetic memory including a magnetic memory element and a recording method thereof, and particularly to a magnetic memory and a recording method thereof suitable for the application to a nonvolatile memory.

2. Description of the Related Art

In information equipment such a computer, a high-speed and high-density DRAM (dynamic random-access memory) is widely used as a random-access memory.

However, the DRAM is a volatile memory of which information is lost when energizing power is removed and hence a nonvolatile memory whose information is not lost even when energizing power is removed is desired.

Then, as a nominated nonvolatile memory, a magnetic random-access memory (MRAM) capable of recording information by using magnetization of a magnetic material receives a remarkable attention and it is now under development (see cited non-patent reference 1, for example).

The MRAM is able to record information by inverting magnetization of a magnetic layer of a magnetic memory element located at an intersection point between address interconnections with an electric current magnetic field generated from respective address interconnections with application of electric currents to two kinds of address interconnections (word line and bit line) which are substantially perpendicular to each other.

FIG. 1 is a schematic diagram (perspective view) of a general MRAM.

As shown in FIG. 1, a drain region 108, a source region 107 and a gate electrode 101 comprising a selection transistor to select each memory cell are constructed on a semiconductor substrate 110 such as a silicon substrate at its portion separated by an element separating layer 102.

Also, a word line 105 extended in the front and back direction in FIG. 1 is located above the gate electrode 101.

The drain region 108 is formed common to right and left selection transistors shown in FIG. 1 and an interconnection 109 is connected to this drain region 108.

A magnetic memory element 103 having a memory layer whose magnetization direction is inverted is disposed between the word line 105 and a bit line 106 located above and which is extended in the right and left direction in FIG. 1. This magnetic memory element 103 is composed of a magnetic tunnel junction element (MTJ element), for example.

Further, the magnetic memory element 103 is electrically connected to the source region 107 through a bypass line 111 extended in the horizontal direction and a contact layer 107 extended in the upper and lower direction.

When electric currents flow through the word line 105 and the bit line 106, a magnetic field of an electric current is applied to the magnetic memory element 103 to invert the magnetization direction of the memory layer of the magnetic memory element 103 to thereby record information.

In the magnetic memory such as the MRAM, in order to hold recorded information stably, it is necessary that the magnetic layer (memory layer) for recording information should have constant coercive force.

On the other hand, in order to rewrite recorded information, it is necessary to apply an electric current of a certain magnitude to the address interconnection.

However, since the address interconnection is reduced in diameter as an element comprising the MRAM is microminiaturized, it becomes difficult to apply a sufficient electric current to the address interconnection.

Accordingly, as an arrangement in which magnetization can be inverted with application of a smaller electric current, a magnetic memory having an arrangement using magnetization inversion by spin injection receives a remarkable attention (see cited patent reference 1, for example).

The magnetization inversion by spin injection is that electrons spin-polarized after they have passed through a magnetic material are injected into other magnetic material to cause magnetization to be inverted in other magnetic material.

When an electric current is applied to a giant magnetoresistive effect element or a magnetic tunnel junction element (MTJ element) in the direction vertical to its film plane, it is possible to invert the magnetization direction of at least a part of a magnetic layer of these elements.

Then, the magnetization inversion by spin injection has an advantage in which magnetization inversion can be realized with application of a small electric current even when the element is microminiaturized.

[Cited non-patent reference 1]: NIKKEI ELECTRONICS 2001, 2. VOL. 12 (pp. 164 to 171).

[Cited patent reference 1]: Official gazette of Japanese laid-open patent application No. 2003-17782

However, according to the arrangement of the related-art MRAM, since only one magnetic memory element is provided at an intersection point between the two address interconnections, a unit by which information can be stored is only one bit.

FIGS. 2 and 3 are schematic diagrams showing a magnetic memory having an arrangement using magnetization inversion by spin injection. FIG. 2 is a perspective view of such a magnetic memory and FIG. 3 is a cross-sectional view thereof.

As shown in FIGS. 2 and 3, a drain region 58, a source region 57 and a gate electrode 51 comprising a selection transistor to select each memory cell are respectively formed on a semiconductor substrate 60 such as a silicon substrate at its portions separated by an element separating layer 52. Of these drain region 58, source region 57 and gate electrode 51, the gate electrode 51 serves as a word line extending in the front and back direction in FIG. 2 as well.

The drain region 58 is formed common to the selection transistor extending in the right and left direction in FIG. 2 and an interconnection 59 is connected to this drain region 58.

Then, a magnetic memory element 53 including a memory layer whose magnetization direction is inverted by spin injection is located between the source region 57 and a bit line 56 located above and which is extended in the right and left direction in FIG. 2. This magnetic memory element 53 is comprised of a magnetic tunnel junction element (MTJ element), for example.

Further, the magnetic memory element 53 is connected to the bit line 56 and the source region 57 through upper and lower contact layers 54, whereby the magnetization direction of the memory layer can be inverted by spin injection with application of an electric current to the magnetic memory element 53.

However, in the magnetic memory having the arrangement using the magnetization inversion by such spin injection, there is proposed only the arrangement in which one magnetic memory element 53 is provided at one intersection point and hence the unit by which information can be stored is only one bit.

Accordingly, in order to realize a higher density magnetic memory, it is necessary to increase the unit by which information can be stored.

As a method for increasing the unit in which information can be stored, there can be considered a method which uses the most advanced microminiaturized semiconductor forming process, a method for forming an address interconnection as a multilayer address interconnection and the like.

However, since the most advanced new manufacturing facilities are required to use the most advanced microminiaturized semiconductor forming process, a problem arises, in which a manufacturing cost is increased unavoidably.

On the other hand, if the unit in which information can be stored is increased by forming the address interconnection as the multilayer address interconnection, then the magnetic memory elements are located close to each other.

As a result, since magnetic interference occurs between the magnetic memory elements located close to each other, a stable recording operation of the magnetic memory becomes difficult.

Also, since the manufacturing process becomes complex, a problem arises in which a yield in the manufacturing process is lowered and in which a manufacturing cost is increased.

### SUMMARY OF THE INVENTION

In view of the aforesaid aspect, the present invention intends to provide a magnetic memory capable of storing much more information per unit area and a recording method thereof.

According to an aspect of the present invention, there is provided a magnetic memory which is comprised of magnetic memory elements having memory layers to hold information by a magnetized state of a magnetic material in which a plurality of magnetic memory elements is electrically connected near an intersection point between two kinds of interconnections which cross with each other and between the two kinds of interconnections in series or in parallel to each other, a plurality of magnetic memory elements has different threshold values of recording currents by which information can be recorded and the memory layers of the respective magnetic memory elements comprise different information storage units.

In accordance with another aspect of the present invention, there is provided a magnetic memory recording method for recording information on a magnetic memory, the magnetic memory comprising magnetic memory elements having memory layers to hold information by a magnetized state of a magnetic material in which a plurality of magnetic memory elements is electrically connected near an intersection point between two kinds of interconnections which cross with each other and between the two kinds of interconnections in series or in parallel to each other, a plurality of magnetic memory elements has different threshold values of recording currents by which information can be recorded and the memory layers of the respective magnetic memory elements comprise different information storage units, the magnetic memory recording method comprising the step of selectively recording information on a plurality of magnetic memory elements by selecting a recording electric current to be an intermediate value between two threshold values of any of threshold values of respective recording currents of a plurality of magnetic memory elements or by selecting a recording electric current to be a value larger than a maximum threshold value.

According to the above-mentioned arrangement of the magnetic memory of the present invention, since a plurality of magnetic memory elements is electrically connected between two kinds of interconnections in series or in parallel to each other and the memory layers of the respective magnetic memory elements comprise different information storage units, respectively, with application of a recording electric current to the magnetic memory element, it becomes possible to record information by inverting the direction of the magnetization of the memory layer by spin injection. Also, as compared with an arrangement of a magnetic memory in which one magnetic memory element is disposed between interconnections, a magnetic memory can be increased in density by increasing the number of the magnetic memory elements per unit volume.

Further, since a plurality of magnetic memory elements connected between the two kinds of interconnections has different threshold values of recording electric currents by which information can be recorded, it becomes possible to selectively record information on a part of or a whole of the magnetic memory elements of a plurality of magnetic memory elements by selecting magnitudes and direction of the electric currents applied to a plurality of magnetic memory elements.

According to the above-mentioned magnetic memory recording method of the present invention, since information is selectively recorded on a plurality of magnetic memory elements of the above-described magnetic memory of the present invention by selecting a recording electric current to be an intermediate value between any two threshold values of threshold values of respective recording electric currents of a plurality of magnetic memory elements or by selecting a recording electric current to be a value larger than a maximum threshold value, it is possible to select a recordable magnetic memory element from a plurality of magnetic memory elements by selecting a magnitude of a recording electric current.

Then, it becomes possible to record arbitrary information on an arbitrary magnetic memory element of a plurality of magnetic memory elements by executing operation for selectively recording information on a part of or a whole of a plurality of magnetic memory elements once or a plurality of combinations of such operations while magnitude and direction of the recording electric current are being selected.

Also, in the above-described magnetic memory of the present invention, the memory layers can be constructed by laminating magnetic layers of at least more than two layers in such a manner that magnetization directions of the upper and lower magnetic layers become anti-parallel to each other.

According to this arrangement, the magnetizations, which are anti-parallel to each other, of the upper and lower magnetic layers can be canceled each other out and a synthesized magnetization of the whole of the memory layers can be decreased. Hence, it becomes possible to change the magnetization direction of the magnetic layer of the memory layer with ease. Consequently, as compared with the case in which the memory layer is comprised of only a magnetic layer of a single layer, it becomes possible to change the direction of the magnetization by a small electric current.

Further, the respective magnetic memory elements, which become different information storage units, of a plurality of magnetic memory elements are made difficult to magnetically interfere with each other. As a result, it becomes possible to record information on the magnetic memory stably and reliably.

Accordingly, it becomes possible to increase the recording density of the magnetic memory without reducing the width of each interconnection.

Further, in the above-described magnetic memory of the present invention, resistance values of a plurality of magnetic memory elements (connected between two kinds of interconnections) can be made substantially equal to each other.

According to this arrangement, although an amount of information that can be recorded on a plurality of magnetic memory elements is decreased, it becomes possible to record arbitrary information on the magnetic memory by one selective recording operation.

According to the above-mentioned present invention, the magnetic memory elements can be located with the high density and the density per unit chip area can be increased, whereby the recording density of the magnetic memory can be increased. Thus, the storage capacity of the magnetic memory can be increased and the magnetic memory can be miniaturized.

Further, according to the present invention, it is possible to selectively record information on a plurality of magnetic memory elements connected between the interconnections by selecting the magnitude of the recording current and its direction (polarity).

Therefore, according to the present invention, it is possible to realize the magnetic memory capable of recording information stably and reliably even when the magnetic memory elements (information storage units) are located with high density.

### BRIEF DESCRIPTION OF THE DRAWINGS

FIG. 1 is a perspective view schematically showing an arrangement of an MRAM according to the related art;

FIG. 2 is a schematic diagram (perspective view) showing an arrangement of a magnetic memory using magnetization inversion by spin injection;

FIG. 3 is a cross-sectional view showing the magnetic memory shown in FIG. 2;

FIG. 4 is a schematic diagram (perspective view) showing an arrangement of a magnetic memory according to an embodiment of the present invention;

FIG. 5A is a schematic cross-sectional view showing the magnetic memory shown in FIG. 4;

FIG. 5B is a schematic diagram showing an equivalent circuit of the magnetic memory shown in FIG. 4;

FIG. 6 is a diagram showing an example of an arrangement of a magnetic memory element of the magnetic memory shown in FIG. 4;

FIG. 7 is a diagram showing a relationship between a write electric current used when magnetization is inverted by spin injection and an element resistance in the magnetic memory element shown in FIG. 6;

FIG. 8 is a diagram used to explain a recording operation in the magnetic memory shown in FIG. 4; and

FIG. 9 is a diagram used to explain a recording operation in a magnetic memory according to another embodiment of the present invention.

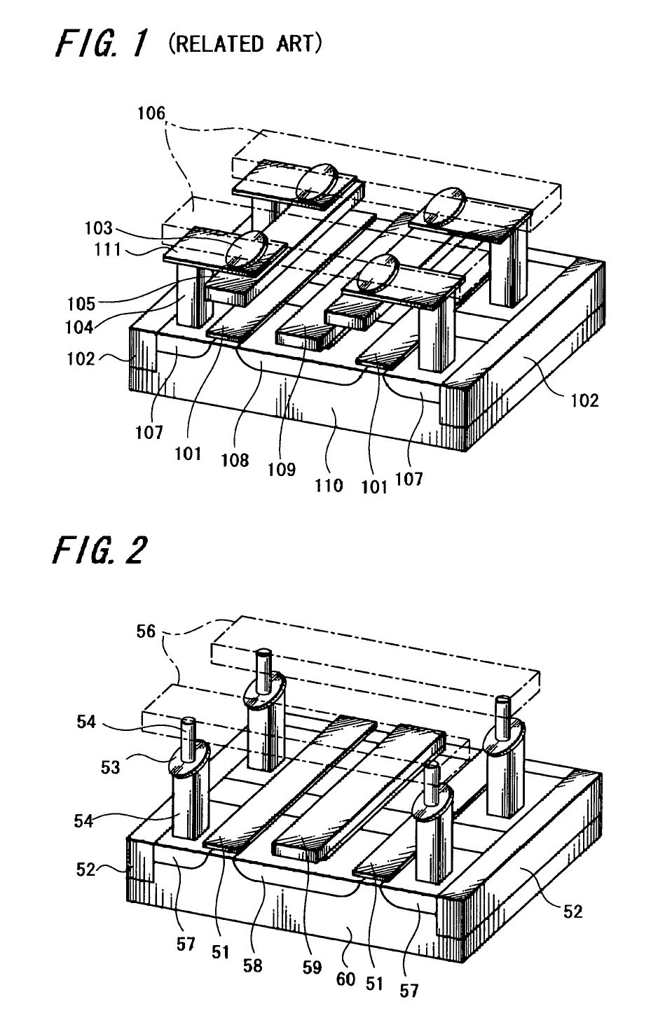

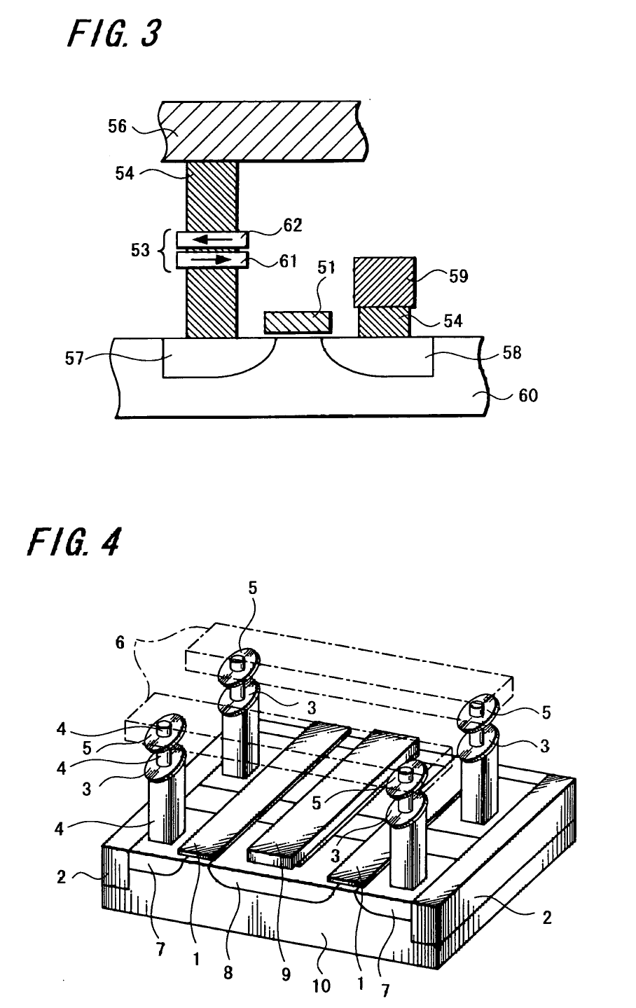

### DESCRIPTION OF THE PREFERRED EMBODIMENTS

Prior to the specific description of the present invention, an outline of the present invention will be described first.

A magnetic memory according to the present invention is able to record information by inverting the magnetization direction of a recording layer of a magnetic memory element with the above-mentioned spin injection.

In the fundamental operation for inverting the magnetization direction of the magnetic layer with the spin injection, an electric current having a magnitude larger than a certain threshold value is applied to a giant magnetoresistive effect element (GMR element) or a magnetic tunnel junction element (MTJ element) in the direction vertical to the film plane. At that time, a polarity (direction) of an electric current depends on the direction of the magnetization to be inverted.

If an electric current having an absolute value smaller than this threshold value is applied to the magnetic memory element, the magnetization direction cannot be inverted.

A threshold value Ic of an electric current required when the direction of the magnetization of the magnetic layer is inverted is expressed by the following equation (1) from a phenomenalism standpoint (see, F. J. Albert et al., Applied Physics Letters, 77, page 3809, 2000, etc., for example).
I_{C}^{±}=kM_{S}V(H_{K}^{effective})/g^{±} (1)
(wherein k is a constant, g^{±} is material-proper inversion coefficient corresponding to positive and negative current polarities, H_{K}^{effective} is effective magnetic anisotropy, M_{S} is saturation magnetization of magnetic layer and V is cubic volume of magnetic layer)

As it is expressed by the above equation (1), the present invention can utilize the fact that a threshold value of an electric current can be set arbitrarily by controlling a volume V of a magnetic layer, a saturated magnetization M_{S} of the magnetic layer and a magnitude of an effective magnetic anisotropy.

Then, the magnetic memory has an arrangement in which a plurality of magnetic memory element having magnetic layers (memory layers) capable of storing information by the magnetization state and which comprises the information storage unit is located between two kinds of interconnection and in which threshold values of electric currents flowing through a plurality of these magnetic memory elements are made different from each other.

According to the above-mentioned arrangement, it becomes possible to selectively record information on a plurality of magnetic memory elements.

A threshold value of an actual electric current is +side threshold value+Ic=+0.6 mA, −side threshold value−Ic=−0.2 mA and an electric current density obtained at that time is approximately 6×10⁶A·cm², which is substantially coincident with the above-described equation (1) in a giant magnetoresistive effect element (GMR element) having an approximately elliptical shape in which a memory layer has a thickness of 2 nm and of which plane pattern is 120 to 130 nm×100 nm (see The Journal of the Magnetic Society of Japan, Vol. 28, No. 2, page 149, 2004, written by Onoue et al.).

On the other hand, an ordinary MRAM for inverting the magnetization with application of an electric current magnetic field needs a write electric current larger than several milliamperes.

Whereas, when the magnetization direction is inverted by spin injection, since the threshold value of the write electric current is decreased to sufficiently small as described above, it is to be understood that this is effective for decreasing a power consumption of an integrated circuit.

Since an interconnection (interconnection 105 shown in FIG. 1) for generating an electric current magnetic field, which is required by the ordinary MRAM, can be removed and this is advantageous from an integration degree standpoint as compared with the ordinary MRAM.

As a method for reading information from the memory layer of the magnetic memory element, a magnetic layer which becomes an information standard may be provided on the memory layer of the magnetic memory element through a thin insulating layer and information of an information storage unit may be read out from the memory layer by a ferromagnetic tunnel electric current flowing through the insulating layer or by a magnetoresistive effect.

Also, in order to read information from a plurality of magnetic memory elements, resistance values of respective states corresponding to the contents of information should be set so as to be separated from each other.

For example, when a magnetic memory element is comprised of a magnetic tunnel junction element (MTJ element), it is generally possible to change resistance values by changing the thickness of a tunnel barrier layer (insulating layer). When the material arrangement is the same, an MR ratio expressed by ΔR/R becomes nearly a constant value. For this reason, if respective resistance values of a plurality of magnetic memory elements are changed, then it becomes possible to separate the resistance values of the respective states from each other.

Subsequently, the embodiment of the present invention will be described.

FIG. 4 is a schematic diagram (perspective view) showing an arrangement of a magnetic memory according to the embodiment of the present invention.

This magnetic memory includes a magnetic memory element capable of recording information in the magnetized state near the intersection point of a plurality of address interconnections (for example, word line and bit line) which are crossing each other.

Specifically, a drain region 8, a source region 7 and a gate electrode 1 comprising a selection transistor to select each memory cell are respectively formed on a semiconductor substrate 10 formed of a silicon substrate, for example, at its portions separated by an element separating layer 2. Of these drain region 8, source region 7 and gate electrode 1, the gate electrode 1 serves as one address interconnection (for example, word line) extending in the front and back direction in FIG. 4 as well.

Then, a magnetic memory element is disposed between the source region 7 and the other address interconnection (for example, bit line) 6 located above and which is extended in the right and left direction in FIG. 4.

The drain region 8 is formed common to selection transistors located in the right and left direction in FIG. 4 and an interconnection 9 is connected to this drain region 8.

In the magnetic memory according to this embodiment, two magnetic memory elements 3 and 5 are located near the intersection point between, in particular, two kinds of the address interconnections 1 and 6.

Then, the magnetic memory element 3 of the lower side and the source region 7; the magnetic memory element 5 of the upper side and the magnetic memory element 3 of the lower side; and the bit line 6 and the magnetic memory element 5 of the upper side are electrically connected to each other through contact layers 4, respectively.

That is, the two magnetic memory elements 3 and 5 are connected in series between the two kinds of the address interconnections 1 and 6 through the selection transistor.

As a consequence, when an electric current is applied between the bit line 6 and the interconnection 9 after the selection transistor was energized with application of the electric current to the word line 1, the magnetization direction of the memory layer is inverted by spin injection with application of the electric current to the two magnetic memory elements 3 and 5 to thereby make it possible to record information on the memory layer.

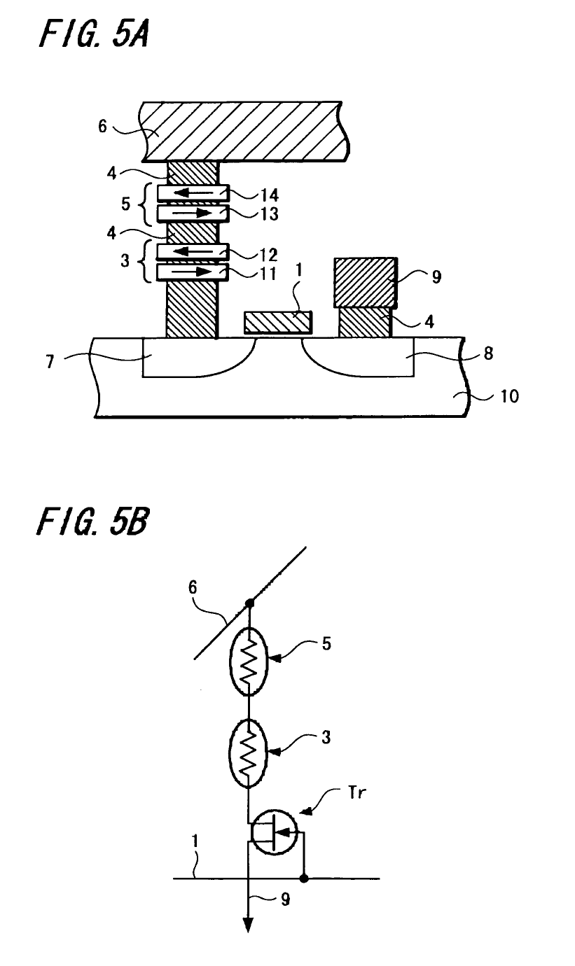

FIG. 5A is a schematic cross-sectional view of the magnetic memory shown in FIG. 4 and FIG. 5B is a schematic diagram showing an equivalent circuit of the magnetic memory shown in FIG. 4.

As shown in FIG. 5A, the two magnetic memory elements 3 and 5 include two magnetic layers 11, 12 and 13, 14 which are magnetically coupled in an anti-parallel fashion, respectively.

As a consequence, in the respective magnetic memory elements 3 and 5, magnetizations of the two layers of the magnetic layers 11, 12 and 13, 14 which are placed in the anti-parallel directions are canceled each other out so that a synthesized magnetization of the whole of the memory layers can be decreased. Thus, it becomes possible to easily change the directions of the magnetizations of the magnetic layers 11, 12 and 13, 14 of the memory layers with application of a small electric current.

Then, it is desired that the two layers of the magnetic layers 11, 12 and 13, 14 comprising the memory layers of the respective magnetic memory elements 3 and 5 should have arrangements in such a manner that they are magnetically coupled in an anti-parallel fashion and that their magnetization amounts may become substantially equal to each other.

According to the above-mentioned arrangements, since a magnetic field leaked from the memory layers of the magnetic memory elements 3 and 5 can be suppressed to the minimum, even when the two magnetic memory elements 3 and 5 are located close to each other, magnetic interferences of the magnetic memory elements 3 and 5 can be decreased, and hence it becomes possible to record and store independent information on the respective magnetic memory elements 3 and 5 which serve as information storage units.

When the two magnetic memory elements 3 and 5 are formed in the upper and lower direction, after the lower-side magnetic memory element 3 was formed, the contact layer 4 may be formed and then the upper-side magnetic memory element 5 may be formed, for example.

Alternatively, after respective layers of the two magnetic memory elements 3 and 5 were sequentially deposited, the respective magnetic memory elements 3 and 5 may be formed by patterning them at the same time.

Further, in the magnetic memory according to this embodiment, in particular, the two magnetic memory elements 3 and 5 have the arrangements in which threshold values of electric currents for inverting the magnetization directions of the memory layers may become different from each other and that resistance values of the magnetic memory elements may become different from each other, as will be described in detail later on.

As a result, it becomes possible to selectively record information on the two magnetic memory elements 3 and 5 and also it becomes possible to read information from the two magnetic memory elements 3 and 5.

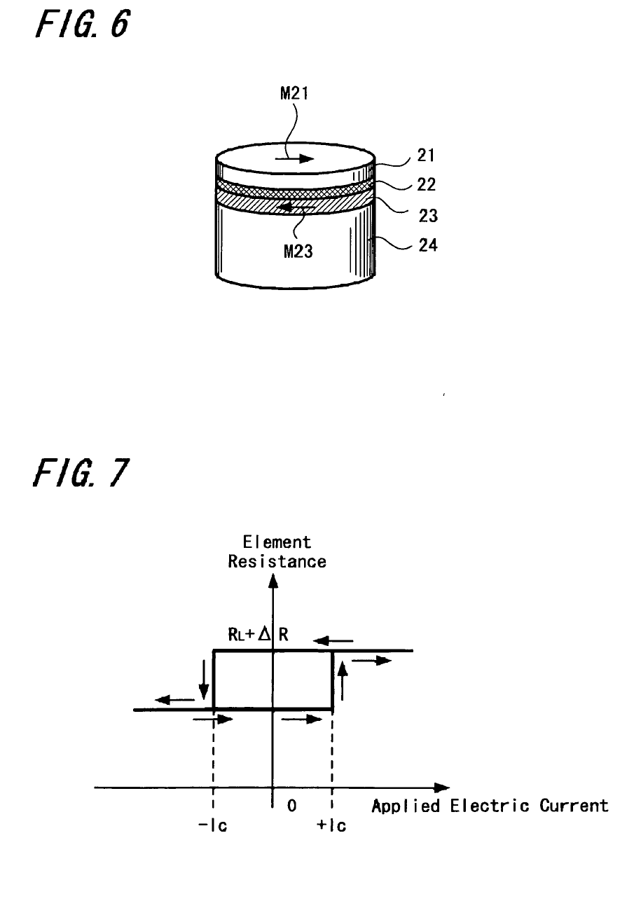

Next, FIG. 6 is a schematic diagram (perspective view) showing an arrangement of an example of the magnetic memory elements (information storage units) 3 and 5 shown in FIG. 4.

In the example shown in FIG. 6, a magnetic memory element is comprised of a magnetic tunnel junction element (MTJ element).

As shown in FIG. 6, a memory layer 21 whose magnetization direction can be inverted and which can record information as the magnetization state, a tunnel insulating layer (tunnel barrier layer) 22, a magnetization fixed layer 23 whose magnetization direction is fixed and an antiferromagnetic material layer 24 to fix the magnetization direction of the magnetization fixed layer 23 are laminated in that order from the upper layer to construct a magnetic tunnel junction element (MTJ element).

The memory layer 21 and the magnetization fixed layer 23 can be made of an alloy such as CoFe, NiFe and CoFeB and the like. The tunnel insulating layer (tunnel barrier layer) 22 can be made of an aluminum oxide which results from oxidizing metal Al. The antiferromagnetic material layer 24 can be made of a suitable material such as PtMn, NiMn, IrMn and FeMn.

In the magnetic memory element according to this embodiment, when the direction of a magnetization M21 of the memory layer 21 and the direction of a magnetization M23 of the magnetization fixed layer 23 are anti-parallel to each other as shown in FIG. 6, a resistance value relative to a tunnel electric current flowing through the tunnel insulating layer 22 is increased.

When on the other hand the direction of the magnetization M21 of the memory layer 21 and the direction of the magnetization M23 of the magnetization fixed layer 23 are parallel to each other, the resistance value of the tunnel electric current flowing through the tunnel insulating layer 22 is decreased.

When the memory layers of the magnetic memory elements 3 and 5 are comprised of the two layers of the magnetic layers 11, 12 and 13, 14 as shown in FIG. 5A, instead of the memory layer 21 composed of the magnetic layer of the single layer shown in FIG. 6, there may be provided a memory layer having an arrangement in which magnetic layers of two layers are disposed in the upper and lower direction through a non-magnetic layer.

FIG. 7 is a diagram showing a relationship between an applied electric current and an element resistance in the magnetic tunnel junction element (MTJ element) having the arrangement shown in FIG. 6 in which its magnetization direction can be inverted by spin injection.

In FIG. 7, an applied electric current for inverting the direction of the magnetization of the memory layer from the state in which a resistance relative to a tunnel electric current flowing through the tunnel insulating layer 22 is low (the state in which the directions of the magnetizations M21, M2 of the memory layer 21 and the magnetization fixed layer 23 are parallel to each other) to the state in which a resistance is high (state in which the directions of the magnetizations M21 and M23 of the memory layer 21 and the magnetization fixed layer 23 are anti-parallel to each other) is assumed to have a +(positive) side polarity and an applied electric current of the opposite direction is assumed to have a −(negative) side polarity. This relationship will apply for other sheets of drawings, which will follow, as well.

Also, in FIG. 7, a threshold value of an applied electric current for inverting the direction of the magnetization of the memory layer is assumed to be +Ic on the +side and it is assumed to be −Ic on the −side, respectively.

A manner in which the element resistance changes in accordance with the change of the applied electric current will be described below with reference to FIG. 7.

The change of the element resistance will be described on the assumption that, in the initial state, the direction of the magnetization M21 of the memory layer 21 and the direction of the magnetization M23 of the magnetization fixed layer 23 are parallel to each other and that the resistance is low (R_{L}).

First, when an electric current larger than the +side threshold value +Ic flows to the +side, the direction of the magnetization M21 of the memory layer 21 is inverted and the direction of the magnetization M21 of the memory layer 21 and the direction of the magnetization M23 of the magnetization fixed layer 23 become anti-parallel to each other, thereby presenting the high resistance state (R_{H}). In FIG. 7, ΔR assumes a difference between the low resistance state (R_{L}) and the high resistance state (R_{H}) and R_{L}+ΔR assumes the high resistance state (R_{H}).

Even when a large electric current flows to the +side much more, the element resistance cannot be changed.

Next, in the high resistance state R_{L}+ΔR, when an electric current larger than the −side threshold value −I_{C} flows to the −side, the direction of the magnetization M21 of the memory layer 21 is inverted and the direction of the magnetization M21 of the memory layer 21 and the direction of the magnetization M23 of the magnetization fixed layer 23 become parallel to each other, thereby presenting the low resistance state (R_{L}).

Even when a larger electric current flows to the −side much more, the element resistance cannot be changed.

In this manner, it becomes possible to record two values of the low resistance state and the high resistance state on the magnetic memory element composed of the magnetic tunnel junction element (MTJ element).

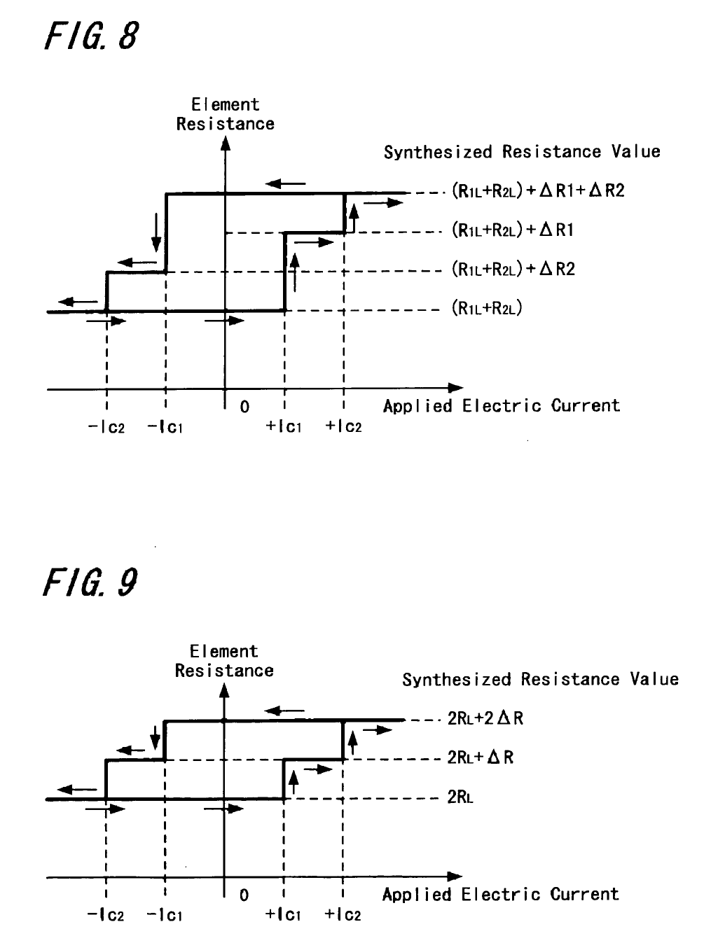

Subsequently, recording operations of the magnetic memory according to this embodiment will be described with reference to FIG. 8.

In the following descriptions, expressions of a first information storage unit and a second information storage unit are used, and of the first information storage unit and the second information storage unit, a unit in which an absolute value of a threshold value of an electric current to invert the direction of the magnetization is smaller is assumed to be the first information storage unit.

Then, with respect to the first information storage unit, a resistance value in the low resistance is assumed to be R_{1L}, a resistance value in the high resistance state is assumed to be R_{1L}+ΔR1 and threshold values of an electric current are assumed to be +I_{C1} and −I_{c1}. With respect to the second information storage unit, a resistance value in the low resistance state is assumed to be R_{2L}, a resistance value in the high resistance state is assumed to be R_{2L}+ΔR2 and the threshold values of the electric current are assumed to be +I_{C2} and −I_{C2}.

For example, in the magnetic tunnel junction element (MTJ element) shown in FIG. 6, the second information storage unit has an arrangement in which its material and area are equal to those of the arrangement of the first information storage unit and in which only the film thickness of the memory layer 21 becomes twice the first information storage unit.

According to the above-mentioned arrangement, from the aforementioned equation (1), the threshold values +I_{C2} and −I_{C2} of the recording current of the second information storage unit become approximately twice the threshold values +I_{C1} and −I_{C1} of the recording current of the first information storage unit.

Then, of the two magnetic memory elements 3 and 5 connected in series shown in FIG. 4 and FIGS. 5A, 5B, any one of the magnetic memory elements is assumed to be the first information storage unit and the other magnetic memory element is assumed to be the second information storage unit.

The symbols (+side and −side) of the threshold values of the electric current may change depending upon the material arrangement (mainly properties of a magnetic material) of the MTJ element. Also, in general, the respective threshold values +I_{C1}, +I_{C2}, —I_{C1}, −I_{C2} have absolute values all of which are different from each other.

In this case, the present invention will be described on the assumption that the respective threshold values are set so as to satisfy −I_{C2}<−I_{C1}<0<+I_{C1}<+I_{C2}.

Also, the low resistance state is assumed to be L and the high resistance state is assumed to be H. Then, the respective resistance states of the first information storage unit and the second information storage unit are expressed as (L, L). The front side within the parenthesis represents the resistance state of the first information storage unit, and the rear side within the parenthesis represents the resistance state of the second information storage unit, respectively.

First, as the initial state, let us consider the state in which the magnetization M21 of the memory layer 21 is directed to the left-hand side contrary to FIG. 6 in the first information storage unit and the second information storage unit. In this case, both of the first information storage unit and the second information storage unit are in the low resistance state and a synthesized series resistance is expressed as (R_{1L}+R_{2L}). This state (L, L) is referred to as the first resistance state of the synthesized series resistance.

Next, when a write electric current I_{WRITE} that can satisfy +I_{C1}<I_{WRITE}<+I_{C2} is applied to the magnetic memory, in the first information storage unit, the direction of the magnetization M21 of the memory layer 21 is inverted and it is directed to the right-hand side so that the resistance value is changed to the high resistance state R_{1L}+ΔR1. However, the direction of the magnetization M21 of the memory layer 21 of the second information storage unit is not inverted and it is still placed in the low resistance state R_{2L}. A synthesized series resistance obtained at that time becomes R_{1L}+R_{2L}+ΔR1. This state (H, L) is referred to as a second resistance state.

Next, when a write electric current I_{WRITE} that can satisfy +I_{C2}<I_{WRITE} is applied to the magnetic memory, both in the first information storage unit and the second information storage unit, the magnetization M21 of the memory layer 21 is directed to the right-hand side and the resistance value is placed in the high resistance state. A synthesized series resistance obtained at that time becomes (R_{1L}+R_{2L}+ΔR1+ΔR2). This state (H, H) is referred to as a third resistance state.

Next, when the polarity of the applied electric current is set to the minus side and a write electric current I_{WRITE} that can satisfy −I_{C2}<I_{WRITE}<−I_{C1} is applied to the magnetic memory, the magnetization M21 of the memory layer 21 of only the first information storage unit is inverted and it is directed to the left-hand side, and hence the resistance is placed in the low resistance state R_{1L}. The direction of the magnetization M21 of the memory layer 21 of the second information storage unit is not inverted and the resistance still remains in the high resistance state R_{2L}+ΔR2. A synthesized series resistance obtained at that time becomes (R_{1L}+R_{2L}+ΔR2). This state (L, H) is referred to as a fourth resistance state.

Next, when a write electric current I_{WRITE} that can satisfy I_{WRITE}<−I_{C2} is applied to the magnetic memory, both in the first information storage unit and the second information storage unit, the magnetization M21 of the memory layer 21 is directed to the left-hand side and the resistance is set to the low resistance state. A synthesized series resistance obtained at that time becomes (R_{1L}+R_{2L}), and the resistance can be returned to the first resistance state (L, L).

In any resistance state, when an electric current I_{WRITE} that falls within a range of —I_{C1}<I_{WRITE}<+I_{C1} is applied to the magnetic memory, the direction of the magnetization of the memory layer cannot be inverted by spin injection. That is, a signal can be read out from the magnetic memory without writing.

In order that all of the possible four resistance states can be distinguished from each other, it is necessary that resistance values among the respective resistance states should be separated from each other.

Accordingly, as shown in FIG. 8, the first information storage unit and the second information storage unit should be constructed in such a manner that ΔR1, ΔR2 and ΔR1+ΔR2 may have different values. Also, it is necessary that the two magnetic memory elements 3 and 5 which become the first information storage unit and the second information storage unit may have resistance values different from each other.

When the above-mentioned arrangement is provided, if the two magnetic memory elements 3 and 5 are composed of the magnetic tunnel junction element (MTJ element) shown in FIG. 6, then material/composition, film thickness and the like of the tunnel insulating layer 23 should be changed.

While ΔR1>ΔR2 is satisfied in FIG. 5, the present invention is not limited thereto and the resistance state may be set so as to satisfy ΔR1<ΔR2.

As described above, when the write electric current that can satisfy the constant condition is applied to the magnetic memory, it is possible for the synthesized series resistance to change its state in the four resistance states from the first resistance state to the fourth resistance state.

Then, it becomes possible to memorize four values by identifying the four resistance states of the synthesized series resistance with a sense amplifier.

Accordingly, it becomes possible to record four values by the two information storage units located near the intersection point between the bit line and the word line, and it is possible to realize a capacity twice as large as that of the magnetic memory of the same area relative to the ordinary arrangement capable of recording two values.

Also, regardless of any of the first to fourth resistance states in which the first information storage unit and the second information storage unit are placed, it is possible to change the synthesized series resistance to other arbitrary state by executing operations to apply the write electric current to the magnetic memory twice at maximum.

For example, by applying an electric current whose absolute value is larger than the threshold value of the second information storage unit, it is possible for the synthesized series resistance to change from other resistance state to the first resistance state and the fourth resistance state by one operation.

For example, while it is not possible for the synthesized series resistance to change its resistance state between the second resistance state and the fourth resistance state, to change its resistance state from the first resistance state to the fourth resistance state and to change its resistance state from the third resistance state to the second resistance state by one operation, it is possible for the synthesized series resistance to change its resistance state by two operations through other resistance state.

While −1_{C2}<−I_{C1}<+I_{C1}<+I_{C2} is assumed in FIG. 8 in order to simplify the description, this condition is not an essential condition but it is sufficient that four threshold values may be different from each other.

According to the above-mentioned arrangement of the magnetic memory of this embodiment, since the two magnetic memory elements 3 and 5 are electrically connected in series between the two kinds of interconnections (for example, word line and bit line) and the memory layers of the respective magnetic memory elements 3 and 5 comprise the different information storage units (first information storage unit and second information storage unit), with application of the electric current to the magnetic memory elements 3 and 5, it is possible to record information by inverting the direction of the magnetization of the memory layer by spin injection.

Then, as compared with the arrangement of the magnetic memory in which one magnetic memory element is located between the two kinds of interconnections, it is possible to make the magnetic memory become high in density by increasing the number of the magnetic memory elements per unit volume.

Also, according to the magnetic memory of this embodiment, since the directions of the magnetizations of the memory layers are inverted and the threshold values of the electric currents by which information can be recorded are different from each other in a plurality of magnetic memory elements 3 and 5 connected between the two kinds of interconnections, it becomes possible to selectively record information on the two magnetic memory elements by selecting the magnitude and direction of the electric current applied to these magnetic memory elements 3 and 5. For example, it is possible to selectively record information on the two magnetic memory elements by selecting the electric current to be the intermediate value between the threshold values of the two magnetic memory elements or by selecting the electric current to be a value larger than a larger threshold value of the threshold values of the two magnetic memory elements.

Thus, four values can be recorded on the two magnetic memory elements.

Therefore, according to the arrangement of the magnetic memory of this embodiment, a density per unit chip area can be increased by locating the magnetic memory elements 3 and 5 with high density and hence the recording density of the magnetic memory can be increased. As a consequence, it is possible to increase the storage capacity of the magnetic memory and to miniaturize the magnetic memory.

Further, since the memory layers of the two magnetic memory elements 3 and 5 are composed of the two magnetic layers 11, 12 and 13, 14 laminated in such a manner that the directions of the magnetizations of the upper and lower magnetic layers may become anti-parallel to each other, the magnetizations of the upper and lower magnetic layers and whose directions are anti-parallel to each other can be canceled each other out and a synthesized magnetization of the whole of the memory layers can be decreased. This, it becomes possible to change the direction of the magnetization of the magnetization layer of the memory layer with ease. As a result, it becomes possible to change the direction of the magnetization with application of a small electric current as compared with the case in which the memory layer is composed of only the magnetic layer of the single layer. Also, it is possible to make the two magnetic memory elements 3 and 5, located in the upper and lower direction, become difficult to magnetically interfere with each other. Thus, it becomes possible to record information on the magnetic memory stably and reliably.

Accordingly, without reducing the width of each interconnection, it becomes possible to increase the recording density of the magnetic memory.

While the memory layers of the magnetic memory elements are composed of the two layers of the magnetic layers 11, 12 and 13, 14 which are magnetically coupled in an anti-parallel fashion in the above-mentioned embodiment, according to the present invention, the memory layer may be formed of a magnetic layer of a single layer, and in addition, the memory layer may be constructed in such a manner that magnetic layers of more than three layers are laminated such that directions of the magnetizations of the upper and lower magnetic layers become anti-parallel to each other.

Further, while the respective magnetic layers 11 to 14 comprising the memory layers are formed of the single layers in the above-mentioned embodiment, according to the present invention, each of the magnetic layers comprising the memory layers of the magnetic memory element may be magnetic layers of single layer. In addition, so long as a magnetic layer can be regarded as a magnetic layer which is uniform to the recording magnetic field, the magnetic layer may have an arrangement in which magnetic layers having different compositions are laminated continuously or an arrangement in which a magnetic layer and a non-magnetic layer are laminated.

Also, while the description of the above-mentioned operation assumes the case in which two magnetic memory elements (information storage units) are connected in series, even when more than three magnetic memory elements (information storage units) are connected in series or in parallel to each other between the two kinds of interconnections (for example, word line and bit line), similarly, information can be selectively recorded on the magnetic memory and information can be read out from the magnetic memory in all states.

When the number of the magnetic memory elements (information storage units) connected between the two kinds of interconnections is assumed to be n, information that can be recorded on the magnetic memory becomes 2ⁿ value so that information of n bits can be recorded.

When the magnetic memory elements (information storage units) are connected in parallel to each other, although a calculation of a synthesized resistance value is different from that of the case in which the magnetic memory elements (information storage units) are connected in series, information can be selectively recorded on the magnetic memory and information can be read out from the magnetic memory similarly.

Next, a magnetic memory according to another embodiment of the present invention will be described.

A schematic arrangement of the magnetic memory according to this embodiment is similar to that of the magnetic memory according to the preceding embodiment shown in FIG. 4 and FIGS. 5A, 5B. Therefore, the arrangements similar to those of the magnetic memory according to the preceding embodiment need not be described. Also, elements and parts identical to those of FIG. 4 and FIGS. 5A, 5B are denoted by identical reference numerals.

In the magnetic memory according to this embodiment, in particular, the two magnetic memory elements 3 and 5 connected in series between the word line 1 and the bit line 6 and whose threshold values of recording currents are different are adapted to have substantially equal resistance values.

When the above-mentioned arrangement is provided, if each of the magnetic memory elements 3 and 5 is composed of the magnetic tunnel junction element (MTJ element) shown in FIG. 7, then it is sufficient that the material/film thickness of the tunnel insulating layer 22 may be selected to be substantially the same.

Next, recording operations of the magnetic memory according to this embodiment will be described with reference to FIG. 9.

In this embodiment, since the two magnetic memory elements 3 and 5 have substantially equal resistance values, R1_{L}=R2_{L}=R_{L} and ΔR1=ΔR2=ΔR are satisfied.

Also, similarly to the case of FIG. 8, the threshold value of the recording current of the first information storage unit (one magnetic memory element) is set to +Ic₁ and −Ic₁, the threshold value of the recording current of the second information storage unit (the other magnetic memory element) is set to +Ic₂ and −Ic₂ and an absolute value of the threshold value of the first information storage unit is smaller than that of the threshold value of the second information storage unit.

First, in the initial state, if the first information storage unit and the second information storage unit are both placed in the low resistance state, then a synthesized series resistance becomes 2R_{L}.

Next, when a write electric current I_{WRITE} that can satisfy +Ic₁<I_{WRITE}<+Ic₂ is applied to the magnetic memory, although the first information storage unit is changed to the high resistance state R_{L}+ΔR, the second information storage unit still remains in the low resistance state R_{L}. A synthesized series resistance obtained at that time becomes 2R_{L}+ΔR.

Next, when a write electric current I_{WRITE} that can satisfy +Ic₂<I_{WRITE} is applied to the magnetic memory, the first information storage unit and the second information storage unit are both placed in the high resistance state R_{L}+ΔR. A synthesized series resistance obtained at that time becomes 2R_{L}+2ΔR.

Next, when the polarity of the applied electric current is set to the −(minus) side and a write electric current I_{WRITE} that can satisfy −I_{C2}<I_{WRITE}<−I_{C1} is applied to the magnetic memory, although only the first information storage unit is changed to the low resistance state R_{L}, the second information storage unit still remains in the high resistance state R_{L}+ΔR. A synthesized series resistance obtained at that time becomes 2R_{L}+ΔR.

Next, when a write electric current I_{WRITE} that can satisfy I_{WRITE}<−I_{C2} is applied to the magnetic memory, both of the first information storage unit and the second information storage unit are placed in the low resistance state R_{L}. A synthesized series resistance obtained at that time becomes 2R_{L}.

In the case of this embodiment, of the aforementioned four combinations of L and H, the synthesized resistance values of (L, H) and (H, L) become the same value as the 2R_{L}+ΔL and hence they may be treated as the same information.

Accordingly, the synthesized resistance values become three values of 2R_{L}, 2R_{L}+ΔR and 2R_{L}+2ΔR and hence ternary information can be recorded on the two magnetic memory elements.

Then, in this case, it is possible to change the resistance state from any ternary states to other binary states by one operation.

The arrangement according to this embodiment is suitable for use with a magnetic memory which is requested to become high in speed rather than it is requested to become large in storage capacity.

Then, as compared with an ordinary system MRAM which does not use the present invention, it is possible to realize the storage capacity as large as approximately 1.5 times by the same chip size in the same write time.

According to the above-mentioned embodiment, similarly to the preceding embodiment, the two magnetic memory elements 3 and 5 can be connected in series between the two kinds of interconnections (for example, word line and bit line) 1 and 6 and the two magnetic memory elements 3 and 5 can be selected by the magnitude of the electric current and the polarity of the electric current and thereby information can be stored in the two magnetic memory elements 3 and 5.

Accordingly, the magnetic memory elements 3 and 5 can be located with high density and the density per unit chip area can be increased, whereby the recording density of the magnetic memory can be increased. As a result, the storage capacity of the magnetic memory can be increased and the magnetic memory can be miniaturized.

Further, according to this embodiment, since it becomes possible to change the resistance state between arbitrary states of the ternary states only by one operation, information can be recorded on the magnetic memory at high speed.

Even when the number of the magnetic memory elements (information storage units) connected between the two kinds of interconnections (for example, word line and bit line) is increased more than three, if the threshold values of the recording electric currents of the respective magnetic memory elements are made different from each other and their resistance values are selected to be substantially the same, then recording operations similar to those of the embodiment shown in FIG. 9 become possible.

If the number of the magnetic memory elements (information storage units) is selected to be n, then information that can be recorded becomes (n+1) value and it can be decreased as compared with 2ⁿ value obtained when the resistance values are made different from each other.

But instead, if the magnitude and direction of the recording electric current are selected, then it is possible to change the resistance state from any states of (n+1) value to other n value states by one operation.

According to the above-mentioned present invention, the magnetic memory elements can be located with the high density and the density per unit chip area can be increased, whereby the recording density of the magnetic memory can be increased. Thus, the storage capacity of the magnetic memory can be increased and the magnetic memory can be miniaturized.

Further, according to the present invention, it is possible to selectively record information on a plurality of magnetic memory elements connected between the interconnections by selecting the magnitude of the recording current and its direction (polarity).

Therefore, according to the present invention, it is possible to realize the magnetic memory capable of recording information stably and reliably even when the magnetic memory elements (information storage units) are located with high density.

It should be understood by those skilled in the art that various modifications, combinations, sub-combinations and alterations may occur depending on design requirements and other factors insofar as they are within the scope of the appended claims or the equivalents thereof.

1. A magnetic memory comprising:
magnetic memory elements having memory layers to hold information by a magnetized state of a magnetic material in which a plurality of magnetic memory elements is electrically connected near an intersection point between two kinds of interconnections which cross with each other and between said two kinds of interconnections in series or in parallel to each other, said plurality of magnetic memory elements has different threshold values of recording currents by which information can be recorded and said memory layers of said respective magnetic memory elements comprise different information storage units.

2. A magnetic memory according to claim 1, wherein said memory layer is constructed by laminating at least more than two magnetic layers in such a manner that magnetization directions of upper and lower magnetic layers become anti-parallel to each other.

3. A magnetic memory according to claim 1, wherein said plurality of magnetic memory elements has resistance values which are substantially equal to each other.

4. A magnetic memory recording method for recording information on a magnetic memory, said magnetic memory comprising:
magnetic memory elements having memory layers to hold information by a magnetized state of a magnetic material in which a plurality of magnetic memory elements is electrically connected near an intersection point between two kinds of interconnections which cross with each other and between said two kinds of interconnections in series or in parallel to each other, said plurality of magnetic memory elements has different threshold values of recording currents by which information can be recorded and said memory layers of said respective magnetic memory elements comprise different information storage units, said magnetic memory recording method comprising the step of:
selectively recording information on said plurality of magnetic memory elements by selecting a recording electric current to be an intermediate value between two threshold values of any of threshold values of respective recording currents of said plurality of magnetic memory elements or by selecting a recording electric current to be a value larger than a maximum threshold value.
